(19) United States
(12) Patent Application Publication
(10) Pub. No.: US 2009/0161471 A1
(43) Pub. Date: Jun. 25, 2009

(54) Power supply device

(75) Inventors: Hai-yi Ji, Shanhai City (CN); Shih-Hao Liu, Taipei (TW)

Correspondence Address: Edwards Angell Palmer & Dodge LLP, P.O. Box 55874, Boston, MA, 02205, US

(73) Assignee: Inventec Corporation, Taipei City (TW)

(21) Appl. No.: 12/004,781

(22) Filed: Dec. 21, 2007

(51) Int. Cl. G11C 5/14

(52) U.S. Cl. 365/226

(57) ABSTRACT

A power supply device is provided according to the present invention. The power supply device is applicable to electronic device, which has a non-volatile memory and a power supply circuit that provides power to the non-volatile memory. The power supply device includes: a power consuming unit for providing the non-volatile memory with a power release path; a control unit electrically connected to the power supply circuit, the non-volatile memory, and the power consuming unit, has and having a first connection end, a switching end, and a second connection end for being selectively electrically connected to the first connection end or the second connection end via the switching end. When the switching end is electrically connected to the first connection end, the power release path between the power consuming unit and the non-volatile memory is disenabled to allow the non-volatile memory to operate normally, and when the switching end is electrically connected to the second connection end, the power release path between the power consuming unit and the non-volatile memory is enabled, thereby executing discharging process of the non-volatile memory via the power consuming unit, and solving many disadvantages of prior art.

### BACKGROUND OF THE INVENTION

1. Field of the Invention

This invention generally relates to a power control technique, and more specifically, to a power supply device for non-volatile memories.

2. Description of Related Art

Non-volatile memories, e.g. complementary metal-oxide semiconductor (CMOS), non-volatile random access memory (NVRAM), etc. are popularly applied in most electronic devices such as personal computers, servers, and so forth; the non-volatile memories are used to store essential data related to operation of the electronic devices, such as information of hard drive allocation, preset parameters of BIOS, and others; therefore, it is essential to keep supplying working power to the non-volatile memories to secure information stored inside the non-volatile memories against being lost.

Please refer to FIG. 1, which is a diagram of prior power supply circuit that provides working power to the non-volatile memory. As shown in the FIG., the power supply circuit 1 includes: a first power supply unit 11 allocated with a battery for supplying 3 volts of a first working power to the non-volatile memory 3; a second power supply unit 13 allocated with a system power for supplying 3.3 volts of a second working power to the non-volatile memory 3; and a switching unit, which is, in this embodiment, a diode 15 that is separately electrically connected to the first and the second power supply units 11 and 13.

Specifically, as shown in FIG. 1, anode of the diode 15 is electrically connected to the first power supply unit 11, and cathode of the diode 15 is electrically connected to the second power supply unit 13; therefore, at the time when the second power supply unit 13 is not connected to the system power but outputs power signal of low potential (0V), the first power supply unit 11 supplies 3 volts of the first working power, therefore, the diode 15 is enabled, and consequently enabling power transmission path between the first power supply unit 11 and the non-volatile memory 3, namely, the first power supply unit 11 supplies power; and then, at the time when the second power supply unit 13 is connected to the system power and outputting power signal of high potential (3.3V), potential at cathode end (3.3V) of the diode 15 is higher than potential at anode end (3.0), therefore the diode 15 is disenabled. At this moment, power supply end of the non-volatile memory is switched from the first power supply unit 11 to the second power supply unit 13 via the diode 15. Accordingly, when an electronic device is not even allocated with a system power, it can be supplied with power via battery installed therein, and as soon as the electronic device is allocated with a system power, the battery installed therein is disenabled to stop supplying power, thereby correspondingly saving power consumption of the battery.

However, sometimes, in order to recover from a system failure of the electronic device, or reset a password in a case of losing original password of the aforesaid non-volatile memory, or for other reasons, information stored in the aforesaid non-volatile memory 3 has to be deleted. Therefore, the aforesaid non-volatile memory 3 needs a discharging process. In summary of working principles of the aforesaid power supply circuit 1, before proceeding to the discharging process of the non-volatile memory 3, the electronic device has to be unplugged to disconnect from power source in order to electrically disconnect the second power supply unit 13 from the system power, next, removing cover body of the case of the electronic device and then removing the battery installed inside on mother board of the electronic device, during this period of time, the non-volatile memory 3 is not supplied with any power, and the discharging process of the non-volatile memory 3 is completed by means of natural power consumption, thereby deleting information stored in the non-volatile memory 3.

However, the aforesaid means of discharging of non-volatile memory has complicated procedure; especially the modern electronic products are in a trend of miniaturization, components are integrated highly densely on a mother board, space for installing a battery is getting smaller and smaller, and therefore, it is getting difficult to remove the battery from the mother board.

In addition, by applying means of natural power consumption, discharging speed is dependent on allocation of chip components inside the non-volatile memory, generally, the discharging speed is slow, and there are different types of non-volatile memories, correspondingly there are different types of allocations of chip components. Therefore, time period of discharging of different types of non-volatile memories is different from one another, so that it is difficult for a user to decide how much time is required for a full discharging process. Further, if a computer is rebooted again before the full discharging process of the non-volatile memory is completed, undeleted messages remained in the non-volatile memory may cause system errors at time of restarting the computer.

Hence, it is an urgent demand for a power supply device, which is easier to manipulate than those in the prior art.

### SUMMARY OF THE INVENTION

In view of the disadvantages of the prior art mentioned above, it is a primary objective of the present invention to provide a power supply device that is easy to manipulate.

It is another objective of the present invention to provide a power supply device for non-volatile memories and for speeding up discharging speed of the non-volatile memories.

To achieve the aforementioned and other objectives, a power supply device is provided according to the present invention. The present invention provides a power supply device for a non-volatile memory of an electronic device, wherein the non-volatile memory has at least one power receiving end, and the power supply device includes a power supply circuit having a first power input end, a power output end, and a first power supply unit that is electrically connecting to the first power input end; a control unit having a first connection end electrically connected to the power output end of the power supply circuit, a second connection end, and one switching end electrically connected to the power receiving end of the non-volatile memory for switching the first connection end and the second connection end to be electrically connected to the power receiving end; and a power consuming unit having a first end electrically connected to the second connection end of the control unit, and a second end electrically grounded.

The power supply circuit further comprises a second power input end; a second power supply unit electrically connected to the second power input end; and a switching unit having a first end electrically connected to the first power input end, and a second end electrically connected to both the power output end and the second power input end.

In accordance with the present invention, voltage of the second power supply unit is higher than voltage of the second power supply unit, and the switching unit is a diode, wherein anode of the diode is electrically connected to the first power supply unit, and cathode of the diode is electrically connected to the second power supply unit.

In addition, in the power supply device of the present invention, the power consuming unit is a resistor; the switching end of the control unit is a selective switch for the non-volatile memory to selectively electrically connect to the power supply unit or the power consuming unit; preferably, the selective switch is allocated on the exterior side of the electronic device for providing users with a convenient way to manipulate.

Moreover, the power supply device of the present invention further comprises a first anti-inference module electrically connected to the power supply circuit and a grounding end for eliminating inference generated while a switching is performed by the selective switch. Preferably, the first anti-inference module is a capacitor.

Furthermore, the power supply device of the present invention further includes a second anti-inference module having a first end electrically connected to the power output end of the power supply circuit, and a second end electrically grounded and being for preventing power supply noise inference and power jitter generated while a switching between the first power supply unit and the second power supply unit is performed. Preferably, the second anti-inference module further includes a second capacitor having a first end electrically connected to the power output end of the power supply circuit, and a second end electrically grounded for providing high frequency filter; and a third capacitor having a first end electrically connected to the power output end of the power supply circuit, and a second end electrically grounded for providing low frequency filter and storing energy.

Compared with the prior art, the power supply device of the present invention includes a power consuming module and a control unit between the power supply circuit and non-volatile memory. Therefore, at the time when the control unit enables power input path between the power supply circuit and the non-volatile memory, it also disenables power release path between the power consuming unit and the non-volatile memory, thereby enabling the non-volatile memory to operate normally, and operation mode at this moment is the same as the mode of power supply of prior power supply circuit; also at the time when the control unit disenables the power input path between the power supply circuit and the non-volatile memory, it correspondingly enables the power release path between the power consuming unit and the non-volatile memory, thereby executing a discharging process of the non-volatile memory via the power consuming unit, accordingly avoiding the complicated discharging process as in the prior art, i.e. power has to be turned off and then battery has to be taken off, and chip units of the non-volatile memory have to go through a full and slow discharging process. Furthermore, compared with the prior means of natural power consumption of the complicated chip units of the non-volatile memory, the power consuming unit provided in the power supply device of the present invention is directly electrically connected to the non-volatile memory for executing discharging process, so that discharging speed of the non-volatile memory is relatively faster, and the discharging speed is easier to master.

### BRIEF DESCRIPTION OF DRAWINGS

The present invention can be more fully understood by reading the following detailed description of the preferred embodiments, with reference made to the accompanying drawings, wherein:

FIG. 1 is a circuit diagram of a prior power supply circuit applied to a non-volatile memory;

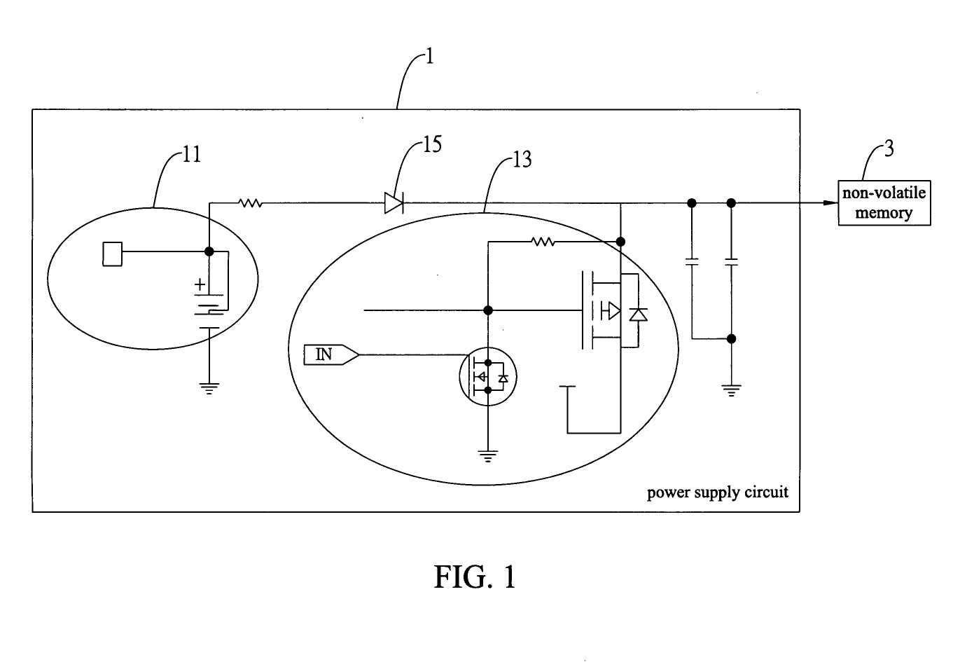

FIG. 2 is a schematic view showing a power supply device for a non-volatile memory according to an embodiment of the present invention;

FIG. 3A is a circuit diagram showing a power supply device for a non-volatile memory according to an embodiment of the present invention;

FIG. 3B is a circuit diagram showing a power supply device for a non-volatile memory according to another embodiment of the present invention;

FIG. 4 is a schematic view showing a power supply device for a non-volatile memory according to another embodiment of the present invention;

FIG. 5A is a circuit diagram showing a power supply device for a non-volatile memory according to another embodiment of the present invention; and

FIG. 5B is a circuit diagram showing a power supply device for a non-volatile memory according to another embodiment of the present invention.

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

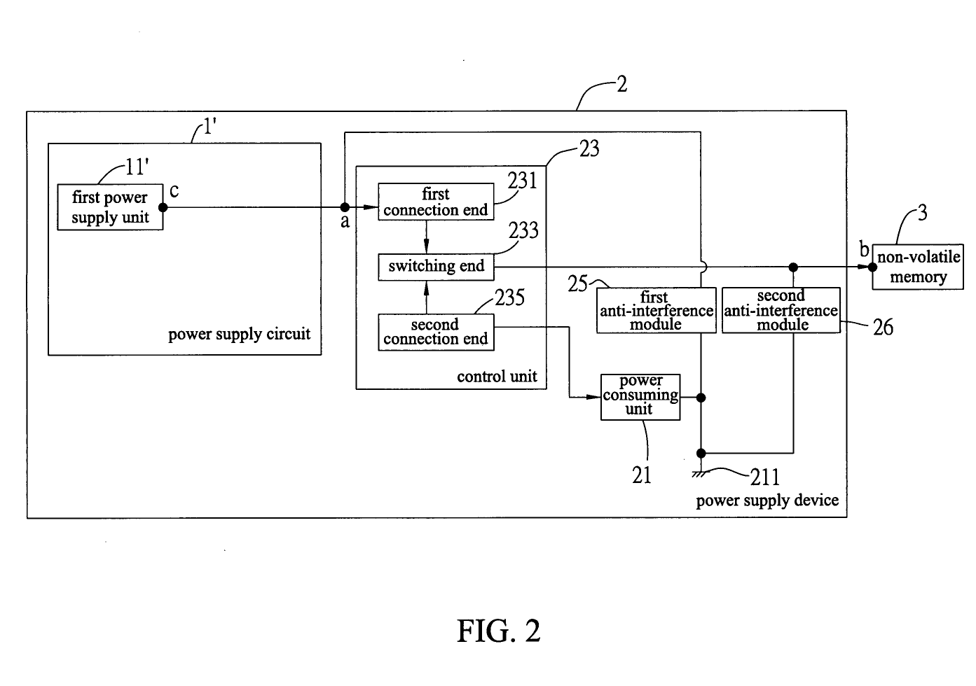

Please refer to FIG. 2, which is a schematic view showing a power supply device for a non-volatile memory according to an embodiment of the present invention.

As shown in FIG. 2, the power supply device 2 of the present invention is applicable to electronic devices, such as personal computers, servers, and others, that have non-volatile memory 3 and power supply circuit 1′. The non-volatile memory 3 is allocated inside the electronic device, and can be complementary metal-oxide semiconductor (CMOS), non-volatile random access memory (NVRAM), and others. The power supply circuit 1′ is used for providing working power to the non-volatile memory 3, and more specifically, the power supply device 2 of the present invention includes a power supply circuit 1′, a power consuming unit 21, and a control unit 23.

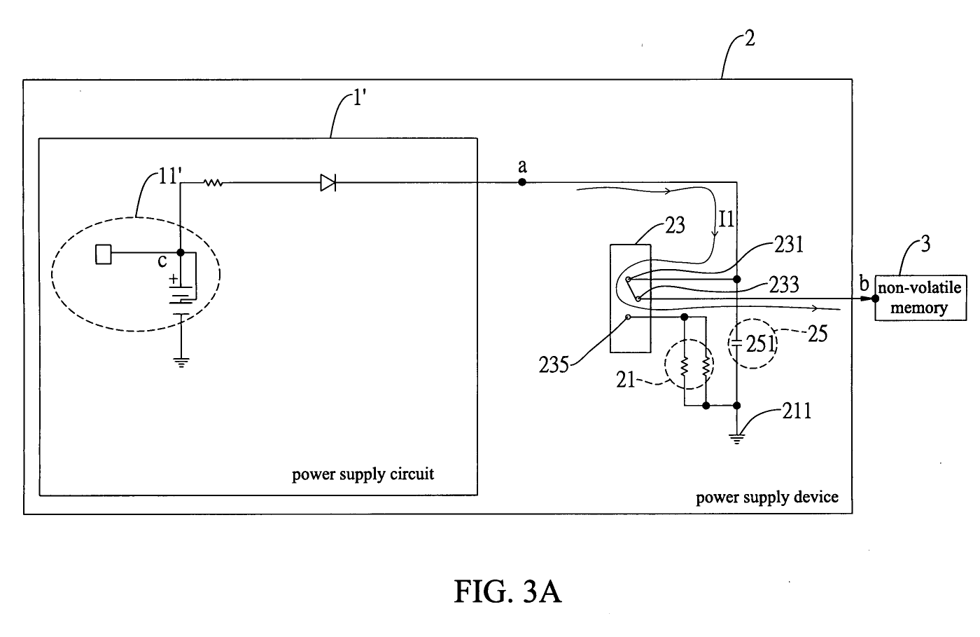

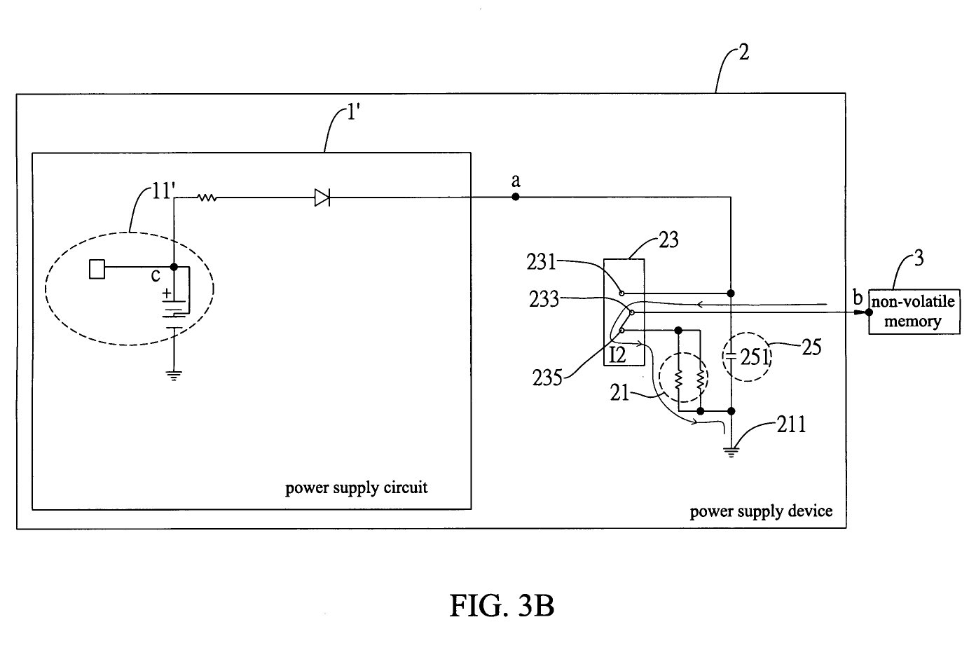

Please refer to FIGS. 3A and 3B along with the following detailed descriptions of each abovementioned item of the power supply device 2 disclosed according to the present invention.

The power supply circuit 1′ includes a power output end 1, a first power input end c, and a first power supply unit 11′, wherein the first power supply unit 11′ is electrically connected to the first power input end c and is allocated with a battery thereon for supplying first working power to the non-volatile memory 3. In the present embodiment, the first working power is 3 volts. Since the power supply principle of the power supply circuit 1′ is well known for persons skilled in the art, it is unnecessary to be described in detail herein.

The power consuming unit 21 is electrically connected to a grounding end 211 for providing the non-volatile memory 3 with a power release path. Preferably, the power consuming unit 21 is a resistor, and resistance of the resistor is capable of determining discharging speed of the non-volatile memory 3. In other words, the smaller the resistance, the faster the discharging speed, and the shorter the time period of discharging. Therefore, users can know how much time is required for a discharging process based on resistance of the resistor 21 in a practical circuit allocation, thereby avoiding disadvantages of the prior art, i.e. time period of discharging is difficult to master, and consequently incomplete discharging is likely to cause system error at time of rebooting in the prior art.

In the present embodiment, as shown in FIG. 3A, the power consuming unit 21 includes two fixed resistors connected in parallel, but it is not restricted to as stated herein, any resistor allocation that is capable of providing required resistance falls in the scope of the present invention. In other embodiments of the present invention, the power consuming unit 21 can also be an adjustable resistor, consequently the discharging speed is adjustable by adjusting the resistance of the adjustable resistor, so that users are capable of easily mastering the discharging speed of the non-volatile memory.

The control unit 23 has a first connection end 231, a switching end 233, and a second connection end 235, which are electrically connected to the power supply circuit 1′, the non-volatile memory 3, and the power consuming unit 21 respectively. The switching end 233 is selectively electrically connected to the first connection end 231 or the second connection end 235, so as to enable or disenable a power input path of power provided by the power supply circuit 1′ and transmitted to the non-volatile memory 3. As shown in FIGS. 3A and 3B, the first connection end 231 of the control unit 23 is electrically connected to a power output end a of the power supply circuit 1′ for receiving first working power from the power supply circuit 1′. In addition, the switching end 233 of the control unit 23 is a selective switch that is for selectively electrically connected to the first connection end 231 or the second connection end 235, so as to electrically connect the non-volatile memory 3 to the power supply circuit 1′ or to the power consuming unit 21. At the time when the switching end 233 is connected to the first connection end 231, i.e. enabling the power input path from the power supply circuit 1′ to the non-volatile memory 3, the switching end 233 is disconnected from the second connection end 235, i.e. disenabling the power release path between the power consuming unit 21 and the non-volatile memory 3. At this moment, the current flow of the power supply device 2 is in a direction as indicated by arrows 11 shown in FIG. 3A, thereby enabling the non-volatile memory 3 to operate normally. At the time when the switching end 233 is connected to the second connection end 235, i.e. enabling the power release path between the power consuming unit 21 and the non-volatile memory 3, the switching end 233 is disconnected from the first connection end 231, i.e. disenabling the power input path from the power supply circuit 1′ to the non-volatile memory 3. At this moment, the current flow of the power supply device 2 is in a direction as indicated by arrows 12 shown in FIG. 3B, thereby executing discharging process of the non-volatile memory 3 via the power consuming unit 21.

Preferably, the switching end 233, e.g. the selective switch, is allocated on exterior side of the electronic device for user to manipulate conveniently. At the time when system failure of the electronic device occurs, or users forget the password of the non-volatile memory 3 and have to reset the password, and the aforesaid non-volatile memory 3 needs a discharging process to delete messages saved in the non-volatile memory 3, all the users have to do is flipping the control unit 23 so as to connect the switch end 233 to the second connection end 235, i.e. enabling the power release path between the power consuming unit 21 and the non-volatile memory 3. The power input path from the power supply circuit 1′ to the non-volatile memory 3 is disenabled. Therefore, the discharging process of the non-volatile memory 3 can be completed without unplugging the electronic device nor consequently taking off battery.

Moreover, the present invention further provides a first anti-inference module 25 electrically connected to the power supply circuit 1′ and the grounding end 211. In the present embodiment, the first anti-inference module 25 is electrically connected to the power output end a of the power supply circuit 1′ and the grounding end 211 for eliminating inference generated at the switching moment of the control unit 23, so as to ensure the power supply device more stable and reliable. Preferably, the first anti-inference module 25 is a first capacitor 251.

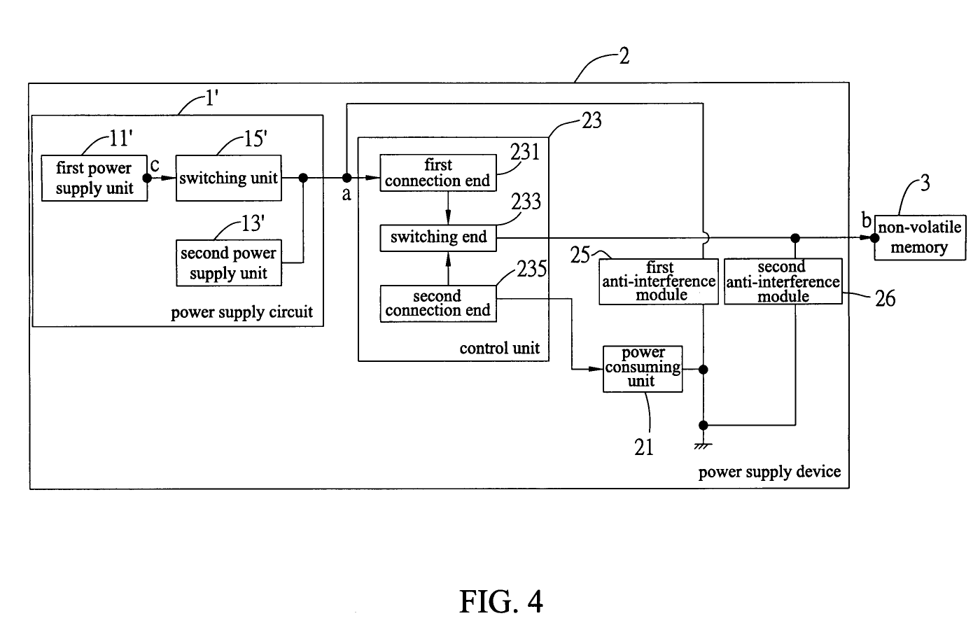

Please refer to FIG. 4, which is a schematic view showing a power supply device for a non-volatile memory according to another embodiment of the present invention.

As shown in the FIG. 4, the power supply device 2 of the present invention includes a power supply circuit 1′, a power consuming unit 21, a control unit, a first anti-inference module 25, and a second anti-inference module 26. The main difference between this embodiment and the aforesaid embodiment is that the power supply circuit 1′ includes a power output end a, a first power input end c, a second power input end d, a first power supply unit 11′ electrically connected to the first power input end c, a second power supply unit 13′ electrically connected to the second power input end d, and a switching unit 15′. The first power supply unit 11′ is allocated with a battery thereon for supplying the non-volatile memory 3 with first working power, and the first working power is 3V in the present embodiment. The second power supply unit 13′ is allocated with a system power thereon for supplying the non-volatile memory 3 with second working power, and the second working power is 3.3V in the present embodiment. The switching unit 15′ has a first end electrically connected to the first power input end c, and a second end electrically connected to the power output end a and the second power input end d. Therefore, when the second power supply unit 13′ is not allocated with the system power, the first power supply unit 11′ supplies the non-volatile memory 3 with the first working power; and when the second power supply unit 13′ is allocated with the system power, the second power supply unit 13′ is switched for supplying the non-volatile memory 3 with the second working power. Consequently, no matter the electronic device is allocated with system power or not, the non-volatile memory 3 is supplied securely with working power to operate normally, and also a power output end a is formed at connection of the switching unit 15′ and the second power supply unit 13′.

In the present embodiment, voltage of the second power supply unit is higher than voltage of the first power supply unit, and the switching unit 15 is a diode, wherein anode of the diode is electrically connected to the first power input end c of the first power supply unit 11′, and cathode of the diode is electrically connected to the power output end a and the second power input end d of the second power supply unit 13′. When the second power supply unit 13′ is not supplying power, the diodes is enabled, and the first power supply unit 11′ supplies power, and when the second power supply unit 13′ is supplying power, the diodes is disenabled, and the second power supply unit 13′ supplies power.

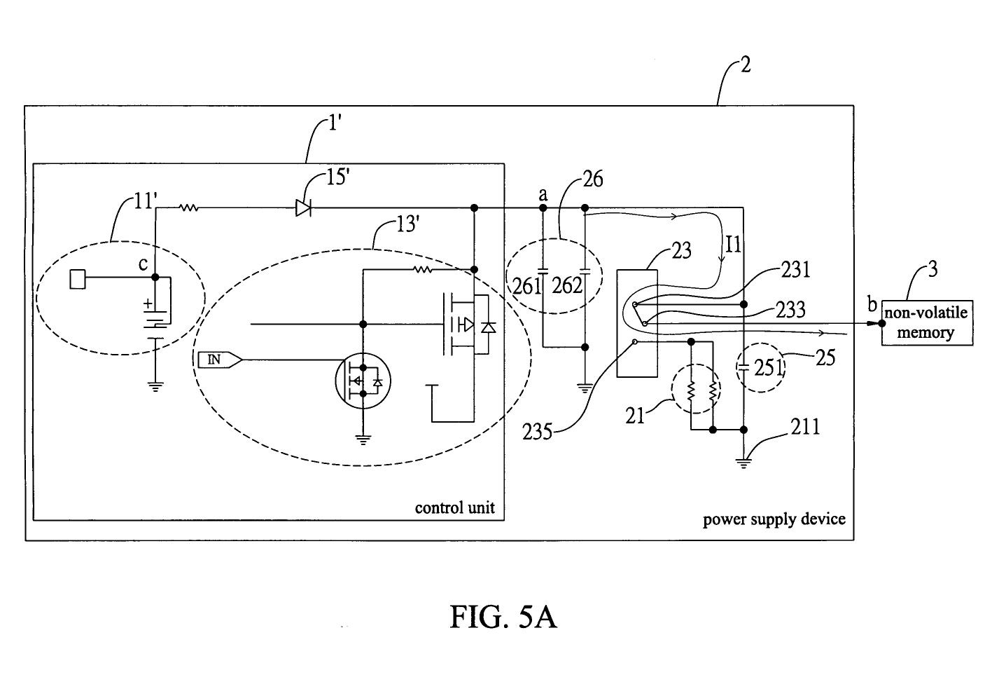

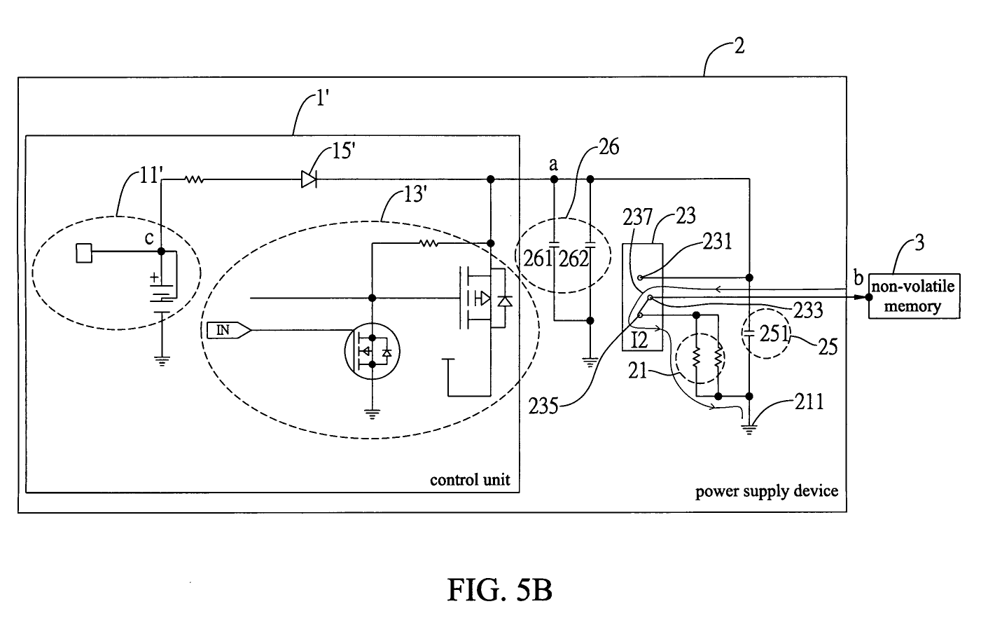

According to the previous descriptions, as shown in FIGS. 5A and 5B, the first connection end 231 of the control unit 23 is electrically connected to the power output end a of the power supply circuit 1′ for receiving the first working power and the second working power from the power supply circuit 1′. Specifically, the switching end 233 of the control unit 23 is also selectively electrically connected to the first connection end 231 or the second connection end 235, so as to enable electricity connection between the non-volatile memory 3 and the power supply circuit 1′ or the power consuming unit 21. When the switch end 233 is connected to the first connection end 231, i.e. enabling the power input path from the power supply circuit 1′ to the non-volatile memory 3, the switching end 233 is disconnected from the second connection end 235, i.e. disenabling the power release path between the power consuming unit 21 and the non-volatile memory 3 At this moment, current flow of the power supply device 2 is in a direction as indicated by arrows I1′ shown in FIG. 5A, thereby enabling the non-volatile memory 3 to operate normally. When the switching end 233 is connected to the second connection end 235, i.e. enabling the power release path between the power consuming unit 21 and the non-volatile memory 3, the switching end 233 is disconnected from the first connection end 231, i.e. disenabling the power input path from the power supply circuit 1′ to the non-volatile memory 3. At this moment, current flow of the power supply device 2 is in a direction as indicated by arrows 12′ shown in FIG. 5B, thereby executing discharging process of the non-volatile memory 3 via the power consuming unit 21.

It is noted that the second anti-inference module 26 has a first end electrically connected to the power output end a of the power supply circuit 1′, and a second end is grounded, and is for preventing from power supply noise inference and power jitter generated while a switching between the first power supply unit 11′ and the second power supply unit 13′ is performed. Preferably, the second anti-inference module 26 further includes a second capacitor 261 having a first end electrically connected to the power output end a of the power supply circuit 1′, and a second end electrically grounded, and being for providing high frequency filter; and a third capacitor 262 having a first end electrically connected to the power output end a of the power supply circuit 1′, and a second end electrically grounded, and being for providing low frequency filter and storing power.

In view of the above, the power supply device of the present invention provides a power consuming module and a control unit to between the prior power supply circuit and non-volatile memory. Consequently, when the control unit enables power input path between the power supply circuit and the non-volatile memory, it also disenables the power release path between the power consuming unit and the non-volatile memory, thereby enabling the non-volatile memory to operate normally, and operation mode at this moment is the same as power supply mode of the prior power supply circuit. When the control unit disenables the power input path between the power supply circuit and the non-volatile memory, it correspondingly enables the power release path between the power consuming unit and the non-volatile memory, thereby executing discharging process of the non-volatile memory via the power consuming unit, and avoiding the complicated discharging process as in the prior art, i.e. power has to be turned off first and then battery has to be taken off, and chip units of the non-volatile memory have to go through a full and slow discharging process in the prior art. Furthermore, compared with the prior means of natural power consumption of the complicated chip units of the non-volatile memory, the power consuming unit provided in the power supply device of the present invention is directly electrically connected to the non-volatile memory for executing discharging process, so that discharging speed of the non-volatile memory is relatively faster, and the discharging speed is easier to master.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A power supply device for a non-volatile memory of an electronic device, wherein the non-volatile memory has at least a power receiving end, the power supply device comprising:
a power supply circuit having a first power input end, a power output end, and a first power supply unit electrically connected to the first power input end;
a control unit having a first connection unit electrically connected to the power output end of the power supply circuit, a second connection end, and a switching end electrically connected to the power receiving end of the non-volatile memory for switching the first connection end and the second connection end to be electrically connected to the power receiving end; and
a power consuming unit having a first end electrically connected to the second connection end of the control unit, and a second end grounded.

2. The power supply device of claim 1, wherein the power supply circuit further comprises:
a second power input end;
a second power supply unit electrically connected to the second power input end; and
a switching unit having a first end electrically connected to the first power input end, and a second end electrically connected to the power output end and the second power input end.

3. The power supply device of claim 1, wherein the first power supply unit is a battery, and the second power supply unit is a system power.

4. The power supply device of claim 2, wherein voltage of the second power supply unit is higher than voltage of the first power supply unit, and the switching unit is a diode, in which anode of the diode is electrically connected to the first power input end of the first power supply unit, and cathode of the diode is electrically connected to the power output end and the second power input end of the second power supply unit; at the time when the second power supply is not supplying power, the diode is enabled, and the first power supply unit supplies power; at the time when the second power supply unit is supplying power, the diode is disenabled, and only the second power supply unit supplies power.

5. The power supply device of claim 1, wherein the power consuming unit is a resistor.

6. The power supply device of claim 1, wherein the switching end of the control unit is a selective switch.

7. The power supply device of claim 6, wherein the selective switch is installed on an exterior side of the electronic device.

8. The power supply device of claim 1, further comprising a first anti-inference module having a first end electrically connected to the first connection end of the control unit, and the a second end electrically grounded, and being for preventing inference generated from the switching end of the control unit while a switching is performed by the switching end.

9. The power supply device of claim 8, wherein the first anti-inference module is a capacitor.

10. The power supply device of claim 2, further comprising a second anti-inference module having a first end electrically connected to the power output end of the power supply circuit, and a second end electrically grounded, and being for preventing power supply noise inference and power jitter generated while a switching between the first power supply unit and the second power supply unit is performed.

11. The power supply device of claim 10, wherein the second anti-inference module comprises:
a second capacitor having a first end electrically connected to the power output end of the power supply circuit, and a second end electrically grounded, and being for providing high frequency filter; and
a third capacitor, one end of the third capacitor is electrically connecting to the power output end of the power supply circuit, and the other is electrically grounding, is and for providing low frequency filter and storing power.

12. The power supply device of claim 1, wherein the non-volatile memory is a complementary metal-oxide semiconductor (CMOS) or a non-volatile random access memory (NVRAM).
